(19) United States
(12) Patent Application Publication
(10) Pub. No.: US 2012/0261730 A1
(43) Pub. Date: Oct. 18, 2012

(54) FLOATING DIFFUSION STRUCTURE FOR AN IMAGE SENSOR

(75) Inventors: Gang Chen, San Jose, CA (US); Hsin-Chih Tai, San Jose, CA (US); Duli Mao, Sunnyvale, CA (US); Howard Rhodes, San Martin, CA (US)

(73) Assignee: OMNIVISION TECHNOLOGIES, INC., Santa Clara, CA (US)

(21) Appl. No.: 13/088,271

(22) Filed: Apr. 15, 2011

(51) Int. Cl. H01L 27/146; H01L 31/18

(52) U.S. Cl. 257/291; 438/57; 257/E27.133; 257/E31.052

(57) ABSTRACT

An image sensor including a pixel array having a floating diffusion region of a pixel which is disposed in a substrate, the floating diffusion region to receive a charge from a photosensitive region. In an embodiment, a transfer gate disposed on the substrate, wherein a portion of the transfer gate forms a cavity extending through the transfer gate. In another embodiment, a cavity extending through a transfer gate exposes a floating diffusion region.

### BACKGROUND

1. Technical Field

This disclosure relates generally to image sensors, and in particular, but not exclusively to complementary metal-oxide semiconductor (“CMOS”) image sensors.

2. Background Art

Image sensors have become ubiquitous. They are widely used in digital still cameras, cellular phones, security cameras, as well as, medical, automobile, and other applications. The technology used to manufacture image sensors, and in particular, complementary metal-oxide-semiconductor (“CMOS”) image sensors (“CIS”), has continued to advance at great pace. For example, the demands of higher resolution and lower power consumption have encouraged the further miniaturization and integration of these image sensors.

Existing CMOS and other image sensors typically include an imaging element having at least one pixel (e.g. 3T pixel, 4T pixel, 5T pixel and/or the like), where the pixel comprises a photodiode or other photosensitive structure to accumulate a charge. Such pixels typically include a transfer gate to regulate a transfer of charge from the photosensitive structure to a floating diffusion (“FD”) node of the pixel. Conversion gain—i.e. a ratio of the change in voltage at the FD node after charge transfer to the change in charge transferred to the FD node—is one metric used to assess the effectiveness of an imaging element. High conversion gain is useful, for example, for an imaging element to capture image data in low-light conditions.

In certain architectures, an image sensor may be comprised of imaging elements which each have two or more pixels. For example, one pixel of such an imaging element may be designed to generate charge for comparatively longer time of integration (to collect more light under low light conditions), and another pixel of the imaging element may be designed to generate charge for comparatively shorter time of integration (for brighter conditions to avoid early saturation). Typically in such an imaging element, each respective FD node of the two or more pixels is coupled to a single common source follower. The coupling of FD node to a single common source follower results in parallel capacitance effects being shared among the respective FD nodes. Therefore, multiple-pixel imaging elements are particularly susceptible to low conversion gain.

However, the effects of FD node capacitance are not limited to multiple-pixel imaging elements. As improvements in miniaturization and integration continue to reduce the size of pixel circuitry, successive generations of single-pixel and multiple-pixel imaging elements are increasingly sensitive to FD node capacitance reducing conversion gain. Consequently, it becomes increasingly challenging to maintain effective levels of conversion gain in successive generations of imaging elements.

### BRIEF DESCRIPTION OF THE DRAWINGS

The various embodiments of the present invention are illustrated by way of example, and not by way of limitation, in the figures of the accompanying drawings and in which:

FIG. 1 is a function block diagram illustrating an image sensor, in accordance with one embodiment.

FIG. 2 is a circuit diagram illustrating pixel circuitry for two four-transistor (“4T”) pixels within a pixel array in accordance with one embodiment.

FIG. 3A is a functional block diagram showing select elements of a pixel including a floating diffusion structure according to an embodiment.

FIG. 3B is a functional block diagram showing select elements of a pixel including a floating diffusion structure according to an embodiment.

FIGS. 4A-4G are block diagrams illustrating cross-sectional views of a process for forming a floating diffusion structure in accordance with one embodiment.

FIG. 5 is a functional block diagram showing select elements of a multiple-pixel imaging element of an image sensor, according to an embodiment.

### DETAILED DESCRIPTION

As discussed herein, certain embodiments variously provide for improvements in conversion gain of an imaging sensor—e.g. conversion gain of a CMOS imaging sensor. More particularly, such techniques variously use, make and/or provide a floating diffusion (“FD”) region (also referred to herein as a “floating diffusion node” or “FD node”) of an image sensor device or system, where a configuration of the FD region results in reduced capacitance, as compared to the FD capacitance of some existing image sensor architectures.

For example, image sensing may be performed with a pixel comprising a substrate having disposed therein a photosensitive region and a FD region. The photosensitive region may capture an electric charge for representing at least part of a captured image. The FD region may receive the charge from the photosensitive region—e.g. as part of a conversion of the captured charge into an analog signal.

The pixel may further comprise a transfer gate disposed on the substrate—e.g. where the captured charge is transferred from the photosensitive region to the FD region in response to a voltage which is provided to the transfer gate. In an embodiment, a portion of the transfer gate forms a cavity which extends through the transfer gate. The cavity may expose the FD region.

By way of illustration and not limitation, the cavity may allow access to the FD region—e.g. for coupling the FD region to a source follower of the pixel. In an embodiment, the FD region may be implanted or otherwise disposed in the substrate through the cavity—e.g. with a process which passively aligns (also referred to herein as self-aligning) the FD region to the portion of the transfer gate which defines the cavity, and/or to one or more structures which are disposed on the substrate and located within the cavity. Accordingly, a transfer gate cavity allows a FD region to be confined to an exposed substrate area which is very small, as compared to the size of FD nodes in existing pixel architectures. Confining an FD region to such a small substrate area results in low FD capacitance, and in a correspondingly large conversion gain of the pixel.

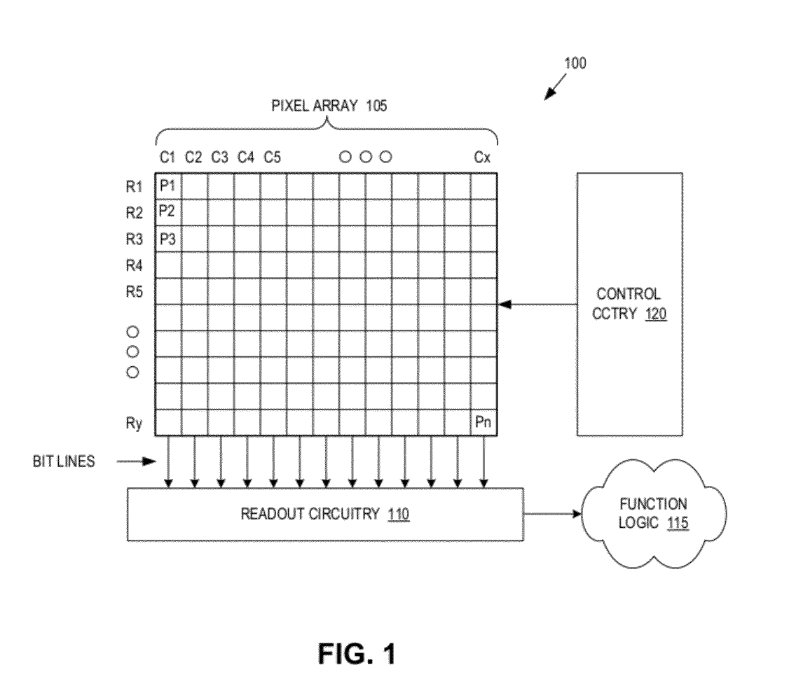

FIG. 1 is a block diagram illustrating an imaging system 100, in accordance with an embodiment of the invention. The illustrated embodiment of imaging system 100 includes a pixel array 105, readout circuitry 110, function logic 115, and control circuitry 120.

Pixel array 105 is a two-dimensional (“2D”) array of imaging sensor cells or pixel cells (e.g., pixels P1, P2 . . . , Pn). As discussed herein, various alternate embodiments may be practiced with an array of imaging elements, where each imaging elements includes one or more pixels. Image data collected from such an imaging element may include an aggregation of respective outputs from all pixels in the imaging element or, alternatively, of respective outputs from only a select one or more pixels in the imaging element.

In one embodiment, pixel array 105 includes is a complementary metal-oxide-semiconductor (“CMOS”) imaging pixel. Pixel array 105 may be implemented as a frontside illuminated image sensor or a backside illuminated image sensor. As illustrated, each pixel is arranged into a row (e.g., rows R1 to Ry) and a column (e.g., column C1 to Cx) to acquire image data of a person, place, or object, which can then be used to render an image of the person, place, or object.

After each pixel has acquired its image data or image charge, the image data is readout by readout circuitry 110 and transferred to function logic 115. Readout circuitry 110 may include amplification circuitry, analog-to-digital (“ADC”) conversion circuitry, or otherwise. Function logic 115 may simply store the image data or even manipulate the image data by applying post image effects (e.g., crop, rotate, remove red eye, adjust brightness, adjust contrast, or otherwise). In one embodiment, readout circuitry 110 may readout a row of image data at a time along readout column lines (illustrated as generic bit lines) or may readout the image data using a variety of other techniques (not illustrated), such as a serial readout, column readout along readout row lines, or a full parallel readout of all pixels simultaneously.

Control circuitry 120 is coupled to pixel array 105 and includes logic for controlling an operational characteristic of pixel array 105. For example, reset, row select, and/or transfer signals may be generated by control circuitry 120, as discussed below. Additionally, dual conversion gain signals or FD boost signals, as discussed below, may also be generated by control circuitry 120. In one embodiment, control circuitry 120 may include photosensitive circuitry to measure the intensity of light impinging upon pixel array 105 and adjust the control signals accordingly.

A typical 4T pixel architecture includes various terminals (e.g., transfer gate, reset gate, reset drain, source follower drain, row select drain, row select gate, and bit line output) that are variously connected along conductive lines to either control circuitry 120 or readout circuitry 110. Some of these terminals may be connected by conductive lines running row-wise (e.g., transfer gate, reset gate, row select), some are connected by conductive lines running column-wise (e.g., bit line output), while still others may be connected by conductive lines running in either row or column directions or even in a grid pattern (e.g., reset drain, source follower drain, row select devices). Thus, a number of conductive lines may run in various directions or patterns. As discussed below, these conductive lines as well as additional lines routed along similar paths may be used to couple supplemental capacitance(s) into the pixel circuitry of each pixel within pixel array 105 to provide a multi conversion gain and/or a FD boost capacitance feature.

High conversion gain can be advantageous for CMOS image sensors operating under low light condition, because the gain is applied at the earliest stage of the signal chain, which produces low read noise. Certain embodiments variously provide structures within an array, such as pixel array 105, to improve conversion gain.

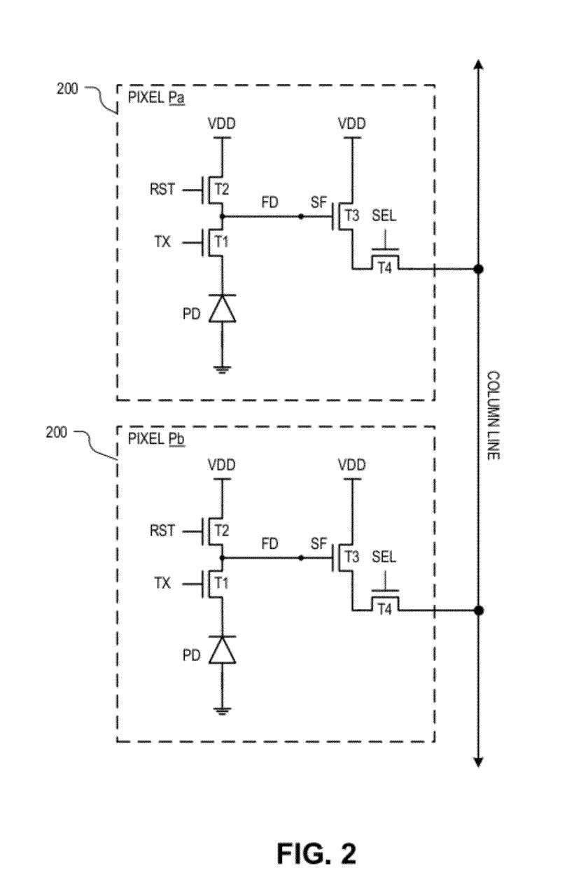

FIG. 2 is a circuit diagram illustrating pixel circuitry of two four-transistor (“4T”) pixel cells Pa and Pb (collectively pixel cells 200) within an image sensor array. Pixel circuitry 200 is one possible pixel circuitry architecture for implementing each pixel within pixel array 105 of FIG. 1, but it should be appreciated that embodiments of the present invention are not limited to 4T pixel architectures; rather, one of ordinary skill in the art having the benefit of the instant disclosure will understand that the present teachings are also applicable to 3T designs, 5T designs, and various other pixel architectures.

Pixel cells Pa and Pb are arranged in two rows and one column and time share a single readout column line. Each pixel cell 200 includes a photodiode PD, a transfer transistor T1, a reset transistor T2, a source-follower (“SF”) or amplifier (“AMP”) transistor T3, and a row select (“RS”) transistor T4.

During operation, transfer transistor T1 receives a transfer signal TX, which transfers the charge accumulated in photodiode PD to a FD node. Reset transistor T2 is coupled between a power rail VDD and the FD node to reset the pixel (e.g., discharge or charge the FD and the PD to a preset voltage) under control of a reset signal RST. The FD node is coupled to control the gate of AMP transistor T3. AMP transistor T3 is coupled between the power rail VDD and RS transistor T4. AMP transistor T3 operates as a source-follower providing a high impedance connection to the FD node. Finally, RS transistor T4 selectively couples the output of the pixel circuitry to the readout column line under control of a signal SEL.

In normal operation, the photodiode PD and the FD node are reset by temporarily asserting the reset signal RST and the transfer signal TX. The image accumulation window (exposure period) is commenced by de-asserting the transfer signal TX and permitting incident light to charge the photodiode PD. As photo-generated electrons accumulate on the photodiode PD, its voltage decreases (electrons are negative charge carriers). The voltage or charge on photodiode PD is indicative of the intensity of the light incident on the photodiode PD during the exposure period. At the end of the exposure period, the reset signal RST is de-asserted to isolate the FD node and the transfer signal TX is asserted to couple the photodiode to the FD node and hence the gate of AMP transistor T3. The charge transfer causes the voltage of the FD node to drop by an amount of proportional to photogenerated electrons accumulated on the photodiode PD during the exposure period. This second voltage biases AMP transistor T3, which is coupled to the readout column line when the signal SEL is asserted on RS transistor T4. Data may be readout from the pixel cell onto the column line as an analog signal. In one embodiment, the TX signal, the RST signal, and the SEL signal are generated by control circuitry 120.

The conversion gain of pixel cells 200 is defined as the ratio (R) of the change in voltage at the FD node after charge transfer to the change in charge transferred to the FD node. Conversion gain (R) is inversely proportional to the capacitance of the FD node. A high conversion gain R can be beneficial, for example, to improve low-light sensitivity.

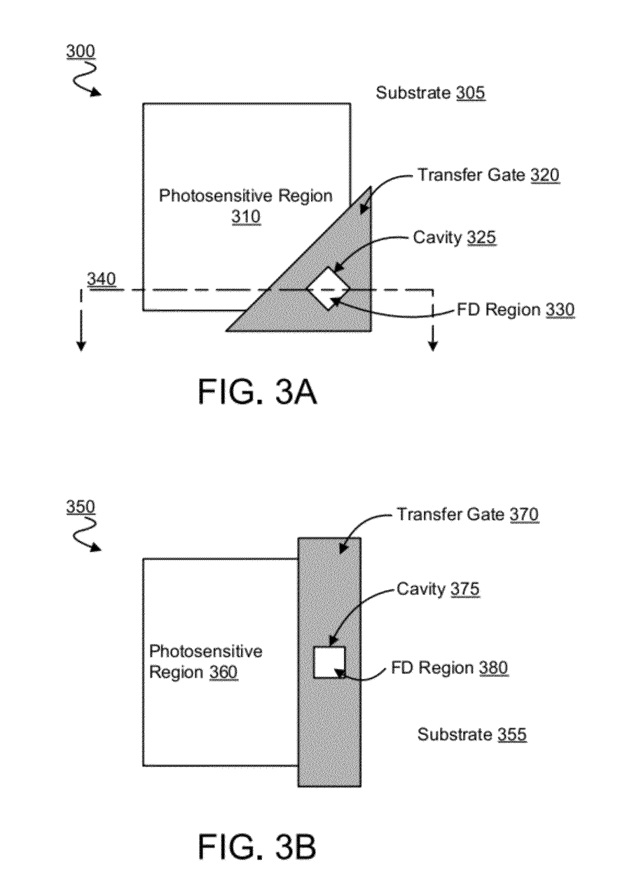

FIG. 3A is a functional block diagram illustrating select elements of a pixel 300 according to an embodiment. Pixel 300 may include some or all of the features of pixel Pa, for example.

Pixel 300 is shown from an elevation facing a surface of substrate 305 in which a photosensitive region 310 is disposed. Substrate 305 may include any of a variety of known semiconductor substrate materials. In an embodiment, photosensitive region 310 may provide the functionality of photodiode PD in pixel 200, for example. More particularly, photosensitive region 310 may include any of a variety of known photosensitive materials and/or structures suitable for storing charge generated by light which is incident upon the photosensitive region 310. Although features of various embodiments are discussed herein with reference to a photodiode, it is understood that such features may be extended to also apply to any of a variety of other suitable photosensitive materials and/or structures.

Pixel 300 may further include a transfer gate 320 to control a transfer of charge from photosensitive region 310—e.g. for generation of a signal representing image data. Transfer gate 320 may, for example, operate as a gate of transistor T1 in pixel 200, although certain embodiments are not limited in this regard. Transfer gate 320 may at least partially overlap a shallow trench isolation (STI) or other isolation structure (not shown) disposed in substrate 305, although certain embodiments are not limited in this regard.

In an embodiment, a portion of transfer gate 320 may form a cavity 325 which extends through transfer gate 320. By way of illustration and not limitation, one or more interior walls of transfer gate may define cavity 325. In an embodiment, an area of substrate 305—e.g. a region including materials and/or structures disposed in substrate 305—may be exposed by the extension of cavity 325 through transfer gate 320. For example, a FD region 330 disposed in substrate 305 may be exposed by cavity 325. In an embodiment, cavity 325 allows access to FD region 330—e.g. for coupling of FD region 330 to a source follower (not shown) or other structure of the pixel.

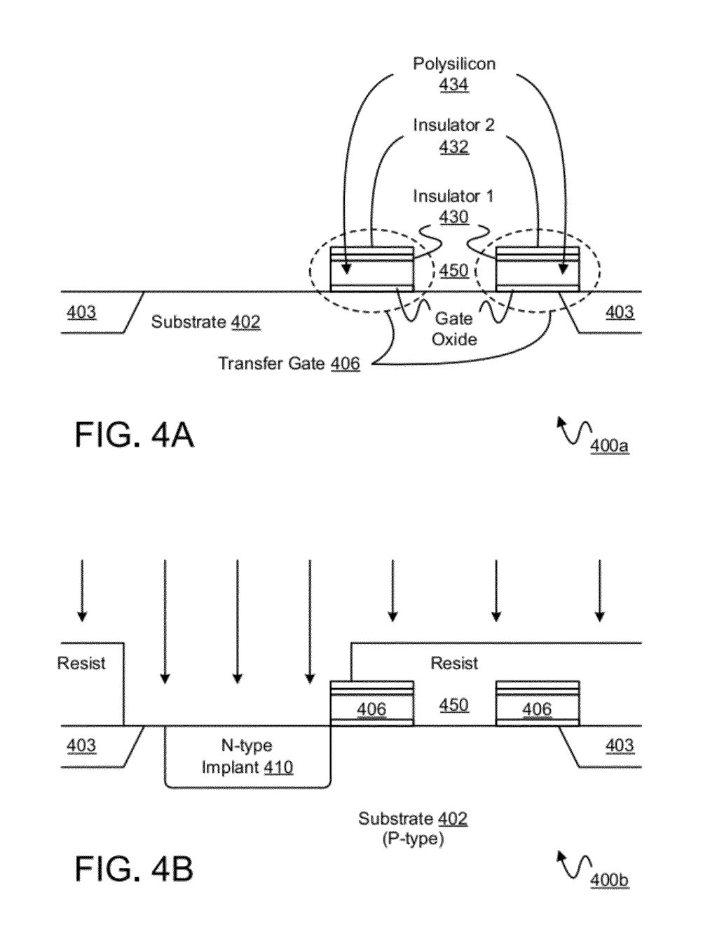

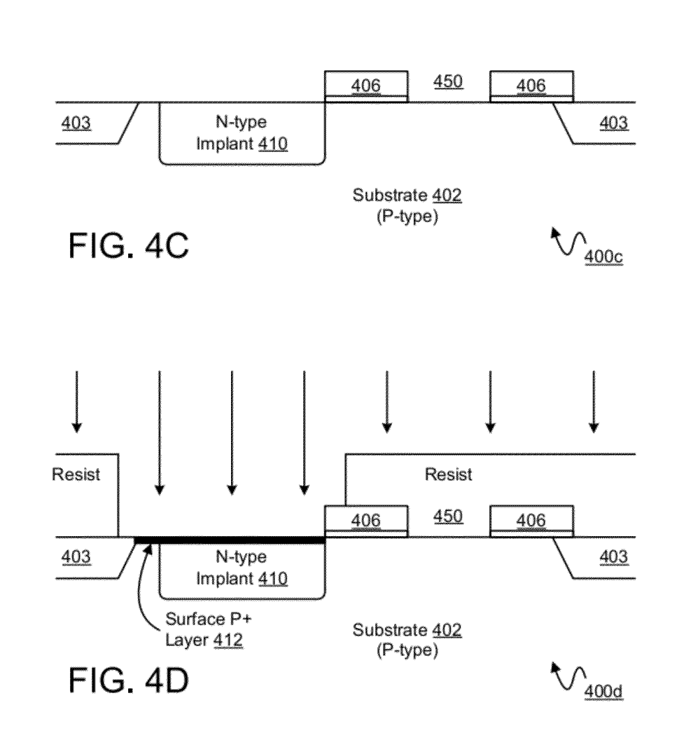

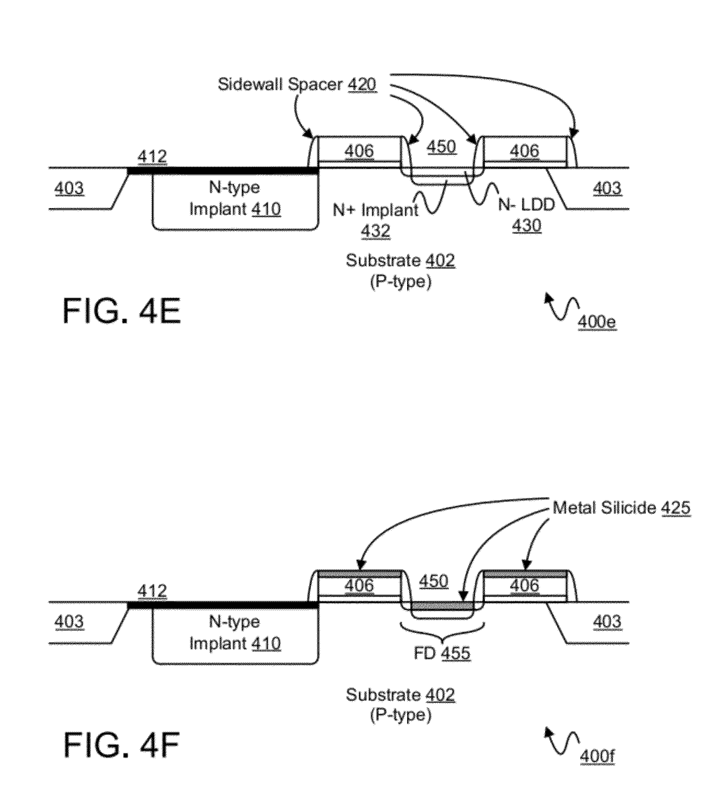

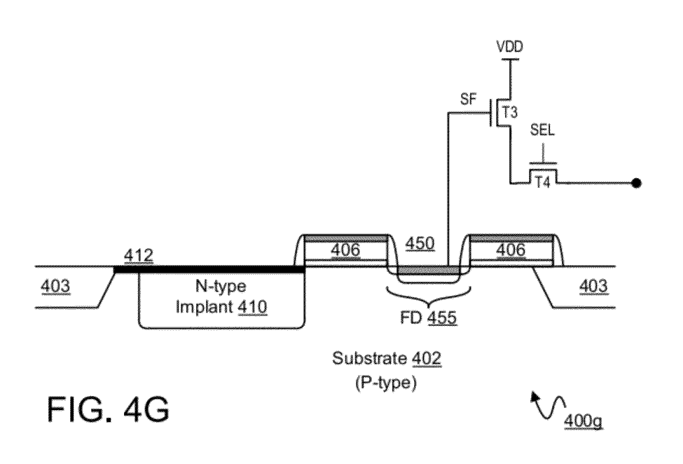

In an embodiment, the surface of FD region 330 may be confined to some portion of the surface of substrate 305 which is exposed by cavity 325. For instance, FD region 330 may be implanted or otherwise disposed in substrate 300 through cavity 325—e.g. with a process in which FD region 330 is self-aligned to the portion of transfer gate 320 which defines cavity 325, and/or self-aligned to a spacer (not shown) or other structure which may be disposed on the substrate and located within cavity 325. A cross-sectional view 340 of structures in a pixel similar to pixel 300 is discussed herein with reference to FIGS. 4A-4G.

FD region 330 may receive the charge generated in photosensitive region 310—e.g. as part of a conversion of the captured charge into an analog image data signal. The captured charge may, for example, be transferred from photosensitive region 310 to FD region 330 in response to a voltage which is provided to transfer gate 320.

The structure of transfer gate 320, particularly the cavity 325 formed thereby, allows FD region 325 to be confined to small area of substrate 305, as compared to the size of FD nodes in existing pixel architectures. The confining of FD region 325 to such a small substrate area may result in low FD capacitance, and in a correspondingly large conversion gain of pixel 300.

FIG. 3B is a functional block diagram illustrating select elements of a pixel 350 according to an embodiment. Pixel 350 may include some or all of the features of pixel Pa, for example.

Pixel 350 is shown from an elevation facing a surface of substrate 355 in which a photosensitive region 360 is disposed. As with pixel 300, pixel 350 may include a transfer gate—e.g. represented by an illustrative transfer gate 370—to control a transfer of charge from photosensitive region 360—e.g. for generation of a signal representing image data. Transfer gate 370 may, for example, operate as a gate of transistor T1 in pixel 200, although certain embodiments are not limited in this regard.

In an embodiment, a portion of transfer gate 370 may form a cavity 375 which extends through transfer gate 370. By way of illustration and not limitation, one or more interior walls of transfer gate may define cavity 375. In an embodiment, an area of substrate 355—e.g. a region including materials and/or structures disposed in substrate 355—may be exposed by the extension of cavity 375 through transfer gate 370. For example, a FD region 380 disposed in substrate 355 may be exposed by cavity 375. In an embodiment, cavity 375 allows access to FD region 380—e.g. for coupling of FD region 380 to a source follower (not shown) or other structure of the pixel.

In an embodiment, the surface of FD region 380 may be confined to some portion of the surface of substrate 355 which is exposed by cavity 375. For instance, FD region 380 may be implanted or otherwise disposed in substrate 350 through cavity 375—e.g. with a process in which FD region 380 is self-aligned to the portion of transfer gate 370 which defines cavity 375, and/or is self-aligned to a spacer (not shown) or other structure which may be disposed on the substrate and located within cavity 375.

Operation of transfer gate 360 to exchange charge from photosensitive region 360 to FD region 380 may correspond generally to operation of transfer gate 320 discussed herein. Transfer gate 370 may include some of the features discussed above with respect to transfer gate 320.

In pixel 300, transfer gate 320 has an external shape—e.g. a triangular outer perimeter formed at least in part by outer walls of transfer gate 320—and location which allows the transfer gate 320 to occupy a corner of a rectangular portion of cell 300 which is defined at least in part by edges of photosensitive region 310. In addition to improved charge transfer characteristics, such a topology may, for example, provide for an improved density of pixels in a pixel array, to allow for smaller and/or higher resolution imaging devices.

By contrast, transfer gate 370 has an external shape and location for the transfer gate 320 to occupy an edge of a rectangular portion of cell 350 which is defined at least in part by edges of photosensitive region 360. It is understood that such external shape and locating of the transfer gate with respect to edges of a photosensitive region may not be limiting on certain embodiments. Although such a topology may result in a comparatively smaller photosensitive region 360, for example, modeling of the performance of such a topology may be easier—e.g. as compared to modeling of pixel 300.

Moreover, while cavities 325, 375 and FD regions 330, 380 are each shown as having a square profile, it is understood that the profile of a cavity and/or the profile of a FD region may not be limiting on various embodiments. By way of illustration and not limitation, a cavity and/or a FD region exposes by such a cavity may each have any of a variety of rectangular (e.g. square) or elliptical (e.g. circular) profiles, according to different embodiments.

FIG. 4A illustrates a view 400a showing select structural elements for a stage in a fabrication process according to an embodiment. In view 400a, a semiconductor substrate 402 is shown which may include, for example, a silicon substrate. A standard isolation 403, such as a shallow trench isolation (STI) may define an active area within the semiconductor substrate 402. In one embodiment, the isolation 403 may be lined with a P-type field implant or other such means for isolation 403 to electrically isolate an active area that will contain a pixel.

In an embodiment, a transfer gate 406 may be formed on substrate 402. As discussed above with respect to FIG. 3A, view 400a—and the views 400b-400g discussed herein—may represent views corresponding to cross-section 340 of pixel 300. For example, view 400a shows in cross-section two different portions of the same transfer gate 406—e.g. where an interior wall and/or other portion of transfer gate 406 defines at least in part the bounds of a cavity 450 for locating a FD node.

Formation of transfer gate 406 may include, for example, deposition or growth of a relatively thin gate oxide layer using conventional semiconductor processing methods, such as thermal growth or chemical vapor deposition. Next, a conductive layer, such as a polysilicon layer 434, may be deposited over the gate oxide layer. In one embodiment, the gate oxide layer is typically 15-100 Å thick and the polysilicon layer 434 is typically between 500 and 2500 Å thick, and more preferably between 1500-2000 Å. However, certain embodiments are not limited in this regard. The polysilicon layer 434 (when patterned, etched, and possibly doped) may serve as the gate of a transfer transistor such as transistor T1 of pixel 200.

Further, a first insulator layer 430 and a second insulator layer 432 may be deposited over the polysilicon layer 434. The first and second insulator layers 430 and 432 are referred to as sacrificial, cap, or disposable insulator layers. As seen below, the disposable insulator may be a metal oxide, silicon oxide, silicon oxynitride, silicon nitride, or combination thereof. They may also serve as an antireflection coating that improves patterning resolution at the transistor gate photolithography step. The first and second insulator layers 430 and 432 may be later removed at an appropriately defined stage in the process—e.g. to allow the subsequent reaction of a metal deposited onto the polysilicon 434 to form the metal silicide.

In one embodiment, the first insulator layer 430 is a silicon oxynitride of thickness between 400-1200 Å, and in one embodiment between 600-1000 Å. The second insulator layer 432 may be a deposited silicon oxide layer having a thickness of between 50-400 Å, and in one embodiment a thickness of between 100-200 Å. However, certain embodiments are not limited in these regards. The use of these materials provides an excellent sacrificial layer that provides good patterning capability for the stack of transfer gate 406.

Alternatively, the disposable insulator layers 432, 434 may be a single nitride or a single silicon oxynitride layer. In such a case, as part of the transistor gate patterning, an organic bottom antireflective coating (ARC) layer may be deposited just prior to the photoresist coating to help better define transfer gate 406. After patterning, the ARC layer may be etched and then the transistor gate stack may be etched in the manner described above. The remaining ARC and photoresist may be stripped after transfer gate 406 has been formed. The cap silicon oxynitride or cap nitride layers may later be removed—e.g. after an N− implant for forming a photodiode. The removal may be done using a wet hot phosphoric acid etch. After removal of these layers, the stack may be patterned and etched to leave the stack structures of transfer gate 406 shown in FIG. 4A.

FIG. 4B illustrates a view 400b showing select elements for a fabrication process stage subsequent to that for view 400a. As shown in view 400b, a photoresist layer may be deposited and patterned to provide an opening for the photodiode formation. After the transistor gate stack 406 has been patterned, the total thickness of the polysilicon, the first insulator layer 430, and the second insulator layer 432 should be thick enough to block the N− buried implant. With a polysilicon thickness of 1800 Å, a silicon oxynitride thickness of 850 Å, and a silicon dioxide thickness of 150 Å, an arsenic implant energy of 180 kev or a phosphorous implant energy of 90 kev can be effectively blocked. The dosage for the N− implant is typically between 1e12 to 7e12 ions/cm². However, certain embodiments are not limited in these regards. The result is that an N-type implant 410 is buried beneath the surface and is self-aligned to the adjacent edge of transfer gate 406.

FIG. 4C illustrates a view 400c showing select elements for a fabrication process stage subsequent to that for view 400b. As shown in view 400c, after the N− implant 410 is formed, the photoresist may be removed, as well as the first insulator layer 430 and the second insulator layer 432. The second insulator layer 432 may be first removed using, for example, a dry, or wet, oxide etch. For example, a wet HF dip which has excellent selectivity to the first insulator layer may be used. The first insulator layer may then be removed using, for example, a dry or wet silicon oxynitride etch. For example, it may be a wet phosphoric etch to limit any reduction to the remaining gate oxide or the silicon surface. At this point, as seen in FIG. 4C, the surface of the polysilicon layer 434 of transfer gate 406 does not have any remaining insulator.

FIG. 4D illustrates a view 400d showing select elements for a fabrication process stage subsequent to that for view 400c. As shown in view 400d, another photoresist layer 450 may be formed with an opening for a P+ pinning layer 412. The P+ implant dose, in one embodiment is 7e12-1e14, and preferably 1e13-5e13 ions/cm². The implant species may be B11, BF2, or indium. If the implant is B11, the implant energy may be 15 kev or less. If the implant species is BF2, the implant energy may be on the order of 10-40 kev. However, certain embodiments are not limited in these regards.

Note that alternatively, the removal of the first and second insulator layers 430 and 432 may be done after the P+ implant instead of after the buried N− implant.

FIG. 4E illustrates a view 400e showing select elements for a fabrication process stage subsequent to that for view 400d. As shown in view 400e, lightly doped drain (LDD) regions 430 may be formed in the region of substrate 402 which is exposed by cavity 450—e.g. by any of a variety of conventional operations. Afterwards, a spacer insulator may be deposited and an anisotropic spacer etch is performed to form sidewall spacers 420 on the sides of transfer gate 406. After spacer formation, an N+ implant region 432 may also be formed in the region exposed by cavity 450—e.g. according to various conventional implant techniques. The N+ implant region 432 may be performed using, for example, an arsenic, phosphorus, or antimony dopant. The spacers 420 may act as a mask for N+ and/or P+ source/drain regions outside of the photodiode.

FIG. 4F illustrates a view 400f showing select elements for a fabrication process stage subsequent to that for view 400e. After sidewall spacers 420 are formed and n+ and p+ implants are implemented, a protective insulator (not shown) may be formed over the top of the structure of FIG. 4E which exposes surfaces of select structures disposed in, and/or disposed on, substrate 402. A metal such as cobalt or titanium may be deposited onto the exposed surfaces of the wafer comprised of substrate 402, and a heat treatment applied to allow the silicon in contact with the metal to react to form regions of metal silicide 425. In an embodiment, an insulation layer (not shown) may limit the areas of the wafer which are to react to the metal. By way of illustration and not limitation, formation of metal silicide 425 may be limited to regions including a surface of transfer gate 406 and a surface exposed by the cavity 450 which is to operate as a FD node 455. The wafer may then be dipped in a wet bath to remove unreacted metal, and not the formed metal silicide 425. Thus, as described above, various embodiments may achieve self-aligned photodiode and transfer gate structures.

FIG. 4G illustrates a view 400g showing select elements for a fabrication process stage subsequent to that for view 400f. In view 400g, a surface of FD node 455 is located in—e.g. confined to—a surface of substrate 402 which is exposed by cavity 450. The surface of FD node 455 is accessible through cavity 450 for coupling to a source follower or other structure of a pixel cell. By way of illustration and not limitation, FD node 455 is coupled to the source follower of the transistor T3 in pixel Pa, although various embodiments are not limited in this regard.

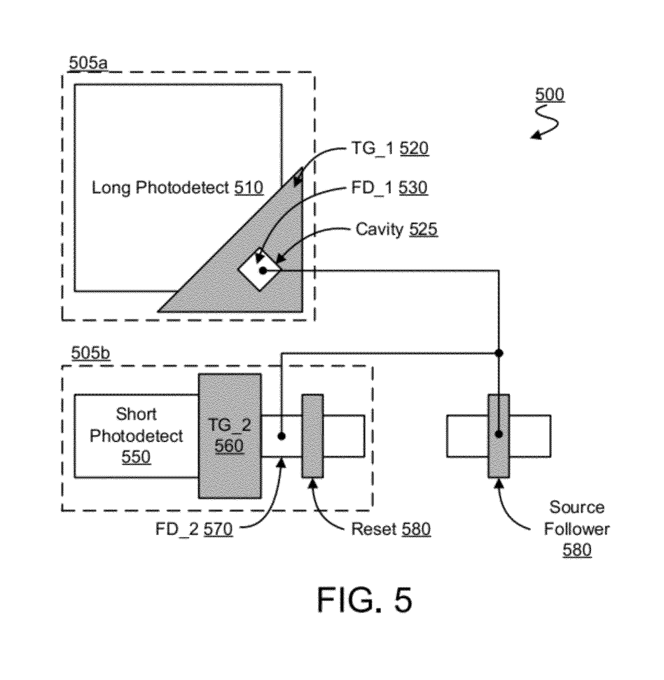

In certain architectures, an image sensor may be comprised of imaging elements, each imaging element having two or more pixels. FIG. 5 illustrates select elements of a multiple-pixel imaging element 500, according to an embodiment.

By way of illustration and not limitation, imaging element 500 may include a first pixel 505a which is designed to generate charge under low light condition, and a second pixel 505b which is designed to capture charge under high light condition. It is understood that imaging element 500 may include any of a variety of combinations of additional or alternative pixels, according to different embodiments.

One or more pixels of imaging element 500—e.g. pixel 505a—may include a topology for a FD layer FD_1 530 according to an embodiment. For example, pixel 505a may include some or all of the features of pixel 300. Alternatively or in addition, a pixel of imaging element 500 may include some or all of the features discussed with respect to pixel 350 and/or the pixel shown in view 400f.

By way of illustration and not limitation, pixel 505a may include a long photodetect 510 which has designed to generate charge under comparatively low light conditions. The charge in long photodetect 510 may be transferred to a FD region FD_1 530 based on a voltage which is applied to a transfer gate TG_1 520—e.g. where FD_1 530 is disposed on an area of a substrate surface which is exposed by a cavity 525 formed by TG_1 520.

In an embodiment, imaging element 500 may include one or more pixels having a conventional architecture. For example, a second pixel 505b of imaging element 500 illustrates one type of conventional pixel, where a rectangular transfer gate TG_2 560 does not form any cavity such as one of those discussed herein. More particularly, a transfer gate TG_2 560 of pixel 505b may be positioned over an area between a FD region FD_2 570 and a photosensitive region—illustrated by short photodetect 550—which is to transfer charge to FD_2 570. In an embodiment, short photodetect 550 is to provide an alternative to pixel 505a, under certain conditions, as a source of image information for imaging element 500.

By way of illustration and not limitation, pixel 505b may include a short photodetect 550 which his designed to generate charge under comparatively low light condition. The charge in short photodetect 550 may be transferred to a FD region FD_2 570 based on a voltage which is applied to a transfer gate TG_2 560. Transfer gate TG_2 560 may be a conventional transfer gate structure at least insofar as TG_2 560 does not form any cavity such as one of those transfer gate cavities discussed herein. A reset gate 580, such as that of transistor T2 in pixel 200, is also shown in pixel 505b, although various embodiments are not limited in this regard.

In multi-pixel imaging element 500, each respective FD region FD_1 530, FD_2 570 of the two or more pixels 505a, 505b is coupled to a single common source follower 580. The coupling of FD regions to a single common source follower 580 may be a source of parallel capacitance effects shared among the FD regions FD_1 530, FD_2 570. However, the small size of FD_1 530 helps mitigate the shared capacitance. As a result, by using transfer gate cavities in sizing and/or positioning FD regions, imaging elements may be designed which have more pixels and/or smaller pixels, while maintaining the levels of conversion gain previously provided in lager pixel architectures.

Techniques and architectures for providing image sensing hardware are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. An image sensor, comprising:
a substrate; and
a pixel array including a plurality of pixels, each of the plurality of pixels including:
a photosensitive region disposed in the substrate;
a transfer gate disposed on the substrate, wherein a portion of the transfer gate forms a cavity extending through the transfer gate; and
a floating diffusion region disposed in the substrate, the floating diffusion region to receive a charge from the photosensitive region, wherein the cavity exposes the floating diffusion region.

2. The image sensor of claim 1, wherein the portion of the transfer gate forming the cavity includes one or more interior sidewalls of the transfer gate.

3. The image sensor of claim 1, wherein the portion of the transfer gate forming the cavity, or structures disposed on the substrate within the cavity, define at least in part a boundary of an exposed surface of the substrate, and wherein the floating diffusion region is aligned to the defined boundary of the exposed surface of the substrate.

4. The image sensor of claim 3, wherein a silicide is disposed on the floating diffusion region, the silicide aligned to the defined boundary of the exposed surface of the substrate.

5. The image sensor of claim 1, wherein the pixel array includes an imaging element having a shared source follower, a first pixel of the plurality of pixels and another pixel, wherein each pixel of the imaging element includes a respective floating diffusion region which is coupled to the shared source follower, wherein the floating diffusion region of the first pixel is coupled to the shared source follower through the cavity extending through the transfer gate of the first pixel.

6. The image sensor of claim 1, wherein the transfer gate includes an outer perimeter having a triangular shape.

7. The image sensor of claim 1, wherein the transfer gate includes an outer perimeter having a rectangular shape.

8. The image sensor of claim 1, wherein the portion of the transfer gate that forms the cavity defines a rectangular boundary of an exposed surface of the substrate, the rectangular boundary defining a perimeter of the floating diffusion region below the transfer gate.

9. The image sensor of claim 1, wherein portion of the transfer gate forming the cavity defines an elliptical boundary of an exposed a surface of the substrate, the elliptical boundary defining a perimeter of the floating diffusion region below the transfer gate.

10. The image sensor of claim 1, wherein the pixel array comprises a complementary metal-oxide semiconductor pixel array.

11. An image sensing pixel, comprising:
a substrate;
a photosensitive region disposed in the substrate;
a transfer gate disposed on the substrate, wherein a portion of the transfer gate forms a cavity extending through the transfer gate; and
a floating diffusion region disposed in the substrate, the floating diffusion region to receive a charge from the photosensitive region, wherein the cavity exposes the floating diffusion region.

12. The image sensing pixel of claim 11, wherein the transfer gate includes an outer perimeter having a triangle shape.

13. The image sensing pixel of claim 11, wherein the transfer gate includes outer walls forming a rectangle.

14. The image sensing pixel of claim 11, wherein the portion of the transfer gate forming the cavity defines a rectangular boundary containing a surface of the exposed floating diffusion region.

15. The image sensing pixel of claim 11, wherein portion of the transfer gate forming the cavity defines an elliptical boundary containing a surface of the exposed floating diffusion region.

16. A method of fabricating a pixel of an image sensor, the method including:
doping a substrate to form a photosensitive region in the substrate;
performing a deposition of a transfer gate on the substrate, wherein a portion of the transfer gate forms a cavity extending through the transfer gate; and
disposing in the substrate a floating diffusion region to receive a charge from the photosensitive region, wherein the cavity exposes the floating diffusion region.

17. The method of claim 16, wherein disposing the floating diffusion region in the substrate includes performing a doping through the cavity of a region of the substrate exposed by the cavity.

18. The method of claim 16, wherein the portion of the transfer gate forming the cavity, or structures disposed on the substrate within the cavity, define at least in part a boundary of an exposed surface of the substrate, and wherein the disposing the floating diffusion region in the substrate includes performing a doping through the cavity to passively align the floating diffusion region to the defined boundary of the exposed surface of the substrate.

19. The method of claim 16, wherein the portion of the transfer gate forming the cavity includes an interior sidewall of the transfer gate, the method further comprising forming a spacer on the inner sidewall of the transfer gate.

20. The method of claim 16, further comprising performing an etch process to form the cavity extending through the transfer gate.
